(19) United States
(12) Patent Application Publication
(10) Pub. No.: US 2026/0156841 A1
(43) Pub. Date: Jun. 4, 2026

(54) SEMICONDUCTOR DEVICES WITH INTEGRATED HIGH DENSITY TRENCH CAPACITOR STRUCTURES

(71) Applicant: TEXAS INSTRUMENTS INCORPORATED, Dallas, TX (US)

(72) Inventors: Yanbiao Pan, Plano, TX (US); Pushpa Mahalingam, Richardson, TX (US)

(21) Appl. No.: 18/965,337

(22) Filed: Dec. 2, 2024

(51) Int. Cl. H01L 21/02

(52) U.S. Cl. CPC H10D 1/042; H10D 1/692

(57) ABSTRACT

Semiconductor devices and fabrication methods thereof are described. For example, a semiconductor device includes a well region disposed in a semiconductor layer, a dielectric layer disposed over the well region and extending above a top surface of the semiconductor layer, an array of trenches disposed within the dielectric layer and the well region extending from a top surface of the dielectric layer into the well region, an insulating layer disposed on sidewalls and bottoms of the trenches, and a conductive layer disposed within the trenches extending from the top surface of the dielectric layer to the insulating layer at the bottoms of the trenches. The semiconductor device further includes a first contact that provides a first terminal connecting to the well region at the top surface of the semiconductor layer, and second contacts that provide a second terminal connecting to top surfaces of the conductive layer within the trenches.

### TECHNICAL FIELD

The present disclosure relates to the field of semiconductor devices, e.g. integrated circuits, and more particularly, but not exclusively, to semiconductor devices with integrated trench capacitor structures.

### BACKGROUND

Integration of capacitor structures into a process flow for fabrication of an integrated circuit presents various challenges. In some approaches, integrated capacitor structures are built on the surface of a semiconductor substrate, using different metal layers in an interconnect structure formed over the surface of the semiconductor structure for the bottom and top plates of the integrated capacitor structures. Such approaches, however, have a limited capacitive density. In other approaches, integrated trench capacitor structures are used to provide higher density capacitor designs. Integrated trench capacitor structures may be formed by forming deep trenches in a highly-doped semiconductor substrate, followed by lining sidewalls and bottoms of the trenches with one or more dielectric layers and filling a conductive layer over the one or more dielectric layers in the trenches.

### SUMMARY

The present disclosure describes semiconductor devices with integrated high density trench capacitor structures and methods of fabrication thereof. This summary is not an extensive overview of the disclosure. Rather, a purpose of the summary is to present some examples of the present disclosure in a simplified form as a prelude to a more detailed description that is presented later.

In some examples, a method of fabricating a semiconductor device includes forming a well region in a semiconductor layer, forming a dielectric layer over the well region that extends upward from a top surface of the semiconductor layer, and forming an array of trenches within the dielectric layer and the well region, the trenches extending from a top surface of the dielectric layer into the well region. The method also includes forming an insulating layer on sidewalls and bottoms of the trenches and forming a conductive layer within the trenches, the conductive layer extending from the top surface of the dielectric layer to the insulating layer at the bottoms of the trenches. The method further includes forming a first contact that provides a first terminal connecting to the well region at the top surface of the semiconductor layer, and forming second contacts that provide a second terminal connecting to top surfaces of the conductive layer within the trenches.

In some other examples, a semiconductor device includes a well region disposed in a semiconductor layer, a dielectric layer disposed over the well region and extending above a top surface of the semiconductor layer, and an array of trenches disposed within the dielectric layer and the well region, the trenches extending from a top surface of the dielectric layer into the well region. The semiconductor device also includes an insulating layer disposed on sidewalls and bottoms of the trenches and a conductive layer disposed within the trenches, the conductive layer extending from the top surface of the dielectric layer to the insulating layer at the bottoms of the trenches. The semiconductor device further includes a first contact that provides a first terminal connecting to the well region at the top surface of the semiconductor layer, and second contacts that provide a second terminal connecting to top surfaces of the conductive layer within the trenches.

In some other examples, a method of fabricating a semiconductor device includes forming a well region in a semiconductor layer and forming an array of trenches within the well region, the trenches extending from a top surface of the semiconductor layer into the well region. The method also includes forming an insulating layer on sidewalls and bottoms of the trenches and forming a conductive layer within the trenches, the conductive layer extending from the top surface of the semiconductor layer to the insulating layer at the bottoms of the trenches. The method further includes forming a first contact that provides a first terminal connecting to the well region at the top surface of the semiconductor layer, and forming second contacts that provide a second terminal connecting to top surfaces of the conductive layer within the trenches.

In some other examples, a semiconductor device includes a well region disposed in a semiconductor layer and an array of trenches disposed within the well region, the trenches extending from a top surface of the semiconductor layer into the well region. The semiconductor device also includes an insulating layer disposed on sidewalls and bottoms of the trenches and a conductive layer disposed within the trenches, the conductive layer extending from the top surface of the semiconductor layer to the insulating layer at the bottoms of the trenches. The semiconductor device further includes a first contact that provides a first terminal connecting to the well region at the top surface of the semiconductor layer, and second contacts that provide a second terminal connecting to top surfaces of the conductive layer within the trenches.

### BRIEF DESCRIPTION OF THE DRAWINGS

FIGS. 1A and 1B are cross-sectional views of a semiconductor device with integrated high density trench capacitor structures in accordance with an example of the present disclosure;

FIGS. 2A-2J are cross-sectional views of a method of fabricating a semiconductor device with integrated high density trench capacitor structures in accordance with an example of the present disclosure;

FIGS. 3A-3C are cross-sectional views of another method of fabricating a semiconductor device with integrated high density trench capacitor structures in accordance with an example of the present disclosure;

FIG. 4 is a cross-sectional view of another semiconductor device with integrated high density trench capacitor structures in accordance with an example of the present disclosure;

FIGS. 5A-5E are cross-sectional views of a method of fabricating a semiconductor device with integrated high density trench capacitor structures in accordance with an example of the present disclosure; and

FIGS. 6A-6C are cross-sectional views of another method of fabricating a semiconductor device with integrated high density trench capacitor structures in accordance with an example of the present disclosure.

### DETAILED DESCRIPTION

The present disclosure is described with reference to the attached figures. The components in the figures are not drawn to scale. Instead, emphasis is placed on clearly illustrating overall features and principles of the present disclosure. Numerous specific details and relationships are set forth with reference to examples of the figures to provide an understanding of the present disclosure. The figures and examples are not meant to limit the scope of the present disclosure to such examples, and other examples are possible by way of interchanging or modifying at least some of the described or illustrated elements. Moreover, where elements of the present disclosure can be partially or fully implemented using known components, certain portions of such components that facilitate an understanding of the present disclosure are described, and detailed descriptions of other portions of such components are omitted so as not to obscure the present disclosure.

As used herein, terms such as “first” and “second” are used to arbitrarily distinguish between the elements such terms describe. Thus, these terms in the description and in the claims are not intended to indicate temporal or other prioritization of such elements. Moreover, terms such as “front,” “back,” “top,” “bottom,” “over,” “under,” “vertical,” “horizontal,” “lateral,” “down,” “up,” “upper,” “lower,” or the like, are used to refer to relative directions or positions of features in devices in view of the orientation shown in the figures. For example, “upper” or “uppermost” can refer to a feature positioned closer to the top of a page than other features. The terms so used are interchangeable under appropriate circumstances such that the examples and illustrations of the technology described herein are, for example, capable of operation in other orientations than those illustrated or otherwise described herein. In the following discussion and in the claims, the terms “including,” “includes,” “having,” “has,” “with,” or variants thereof are intended to be inclusive in a manner similar to the term “comprising,” and thus should be interpreted to mean, for example, “including, but not limited to.” Further, in some examples, the terms “about” or “approximately” preceding a value mean +/−10-20 percent of the stated value. The terms “substantially” or “substantially equal” means values within ±2.5% of the stated value. Still further, unless otherwise specified, the ordering of steps in the description and in the claims are not intended to limit sequencing of the performance of steps and thus alternate step sequencing is contemplated as appropriate.

Various structures disclosed herein can be formed using semiconductor process techniques. Layers including a variety of materials can be formed over a substrate (e.g., a semiconductor wafer), for example, using deposition techniques (e.g., chemical vapor deposition, physical vapor deposition, atomic layer deposition, spin coating, plating), thermal process techniques (e.g., oxidation, nitridation, epitaxy), and/or other suitable techniques. Similarly, some portions of the layers can be selectively removed, for example, using etching techniques (e.g., plasma (or dry) etching, wet etching), chemical mechanical planarization, and/or other suitable techniques, some of which may be combined with photolithography steps. The conductivity (or resistivity) of the substrate (or regions of the substrate) can be controlled by doping techniques using various chemical species (which may also be referred to as dopants, dopant atoms, or the like) including, but not limited to, boron, gallium, indium, arsenic, phosphorus, or antimony. Doping may be performed during the initial formation or growth of the substrate (or an epitaxial layer grown on the substrate), by ion-implantation, or other suitable doping techniques.

As mentioned, integrated trench capacitor structures may be used to provide high density capacitor designs. The density of integrated trench capacitor structures, also referred to as deep trench capacitor structures, is limited by how many trench capacitors can be placed in a given area. Further increasing the capacitor density is conventionally thought to require shrinking the trench capacitor (Tcap) diameter and spacing (e.g., pitch), which requires redesigning layouts while ensuring that design rules and constraints are not violated.

Integrated trench capacitor structures may require added shallow trench isolation (STI) structures at trench edges to protect the dielectric at the top of the trenches. Further, when the top plate of the trench capacitor structures is polysilicon, a silicide block (SIBLK) layer needs to be patterned between each of the trench capacitor structures to ensure that only the center of the top plate of each of the trench capacitor structures is silicided in order to ensure that the top and bottom plates of the trench capacitor structures are disconnected from one another. These layout requirements complicate the fabrication process, and also lead to design rules and constraints related to the masks (e.g., for making the STI structures and SIBLK layer) that limit how much the Tcap diameter and spacing can be shrunk. Reducing the Tcap diameter and/or spacing too much may violate these design rules and constraints. Illustrative embodiments provide methods for fabricating integrated trench capacitor structures after the STI structures are formed, which advantageously allows for improving the trench capacitor density without violating design rules and constraints. Illustrative embodiments also permit the use of various materials as a conductive layer that fills the trench capacitors, including doped polysilicon, a metal such as tungsten (W) or aluminum (Al), etc.

In some examples, integrated trench capacitor structures are formed after STI structures are formed, and are placed on top of an oxide layer over the surface of the silicon or other semiconductor substrate (also referred to herein as a MOAT region). The MOAT or STI structure layout mask is thus designed to completely encompass the Tcap region (e.g., an area of the semiconductor substate where an array of trenches are formed for the integrated trench capacitor structures). Using the process flows described herein, STI structures are advantageously not needed to protect the dielectric on the top surface of the semiconductor substrate to avoid connection between top and bottom terminals of the integrated trench capacitor structures, as the integrated trench capacitor structures have inherently isolated top and bottom terminals. Further, because the integrated trench capacitor structures have inherently isolated top and bottom terminals, the trenches may be made deeper than otherwise possible to gain more capacitance.

In some examples, the high density integrated trench capacitor structures described herein can enable approximately a three times increase in capacitor density (e.g., from about 18.4 femtofarads per micrometer squared (fF/μm²) up to about 56 fF/μm²) as compared to baseline trench capacitors. Moreover, capacitors formed consistent with the disclosure show reduced capacitor vertical resistance and improved sheet resistance uniformity. Trench diameter and trench spacing can also be significantly reduced. In some examples, the trench diameter is reduced from about 1.2 μm to about 0.3 μm while the trench spacing is reduced from about 0.6 μm to about 0.25 μm, as the novel fabrication processes described herein are not subject to the design rule limitations related to MOAT/STI and SIBLK reticles. In some examples, integrated trench capacitor structures may be formed with a Tcap diameter/spacing of 1.1/0.3 with a capacitor density of approximately 31. The novel high density integrated trench capacitor structures described herein can also advantageously support high voltage applications (e.g., 20 V applications).

The novel fabrication processes described herein may utilize one mask for forming the array of trenches in the semiconductor substrate, and may utilize a heavy N+ implant and thermal drive-in to form an N+ bottom plate for the integrated trench capacitors after the array of trenches is formed, followed by formation (e.g., thermal growth or a suitable deposition process) for forming dielectric layers (e.g., one or more oxide and nitride layers) on sidewalls and bottoms of the trenches, followed by fill of a conductive layer (e.g., doped polysilicon, a metal such as W or Al, etc.) in the trenches. The novel integration flow enables the trench formation to be inserted after formation of the STI structures in the fabrication process, and allows for usage of metal or doped polysilicon to fill the top plate of the integrated trench capacitor structures.

In some examples, a method of fabricating a semiconductor device includes forming a well region in a semiconductor layer, forming a dielectric layer over the well region that extends upward from a top surface of the semiconductor layer, and forming an array of trenches within the dielectric layer and the well region, the trenches extending from a top surface of the dielectric layer into the well region. The method also includes forming an insulating layer on sidewalls and bottoms of the trenches and forming a conductive layer within the trenches, the conductive layer extending from the top surface of the dielectric layer to the insulating layer at the bottoms of the trenches. The method further includes forming a first contact that provides a first terminal connecting to the well region at the top surface of the semiconductor layer, and forming second contacts that provide a second terminal connecting to top surfaces of the conductive layer within the trenches. The top surfaces of the conductive layer within the trenches may be coplanar with the top surface of the dielectric layer formed over the well region. The well region may have a first conductivity type and the semiconductor layer may have a second conductivity type, and the semiconductor layer may include a buried layer having the first conductivity type, and the trenches may extend from the top surface of the dielectric layer and through the well region to the buried layer. The conductive layer may include metal electrodes or polysilicon.

Forming the array of trenches may include patterning a mask layer over the dielectric layer, and etching portions of the dielectric layer and underlying portions of the semiconductor layer exposed by the mask layer to form the array of trenches. Forming the well region may include performing an angled ion implantation self-aligned to the array of trenches.

Forming the insulating layer and forming the conductive layer may include depositing one or more layers of insulating material over the dielectric layer and on the sidewalls and the bottoms of the trenches, filling a conductive material over the one or more layers of insulating material, and performing a planarization process to remove portions of the conductive material, the one or more layers of insulating material and the dielectric layer, where remaining portions of the one or more layers of insulating material provide the insulating layer and remaining portions of the conductive material provide the conductive layer.

In some other examples, a semiconductor device includes a well region disposed in a semiconductor layer, a dielectric layer disposed over the well region and extending above a top surface of the semiconductor layer, and an array of trenches disposed within the dielectric layer and the well region, the trenches extending from a top surface of the dielectric layer into the well region. The semiconductor device also includes an insulating layer disposed on sidewalls and bottoms of the trenches and a conductive layer disposed within the trenches, the conductive layer extending from the top surface of the dielectric layer to the insulating layer at the bottoms of the trenches. The semiconductor device further includes a first contact that provides a first terminal connecting to the well region at the top surface of the semiconductor layer, and second contacts that provide a second terminal connecting to top surfaces of the conductive layer within the trenches. The top surfaces of the conductive layer within the trenches may be coplanar with the top surface of the dielectric layer formed over the well region. The well region may have a first conductivity type and the semiconductor layer may have a second conductivity type, the semiconductor layer may include a buried layer having the first conductivity type, and the trenches may extend from the top surface of the dielectric layer and through the well region to the buried layer. The conductive layer may be metal electrodes or polysilicon. The dielectric layer may be a nitride material.

In some other examples, a method of fabricating a semiconductor device includes forming a well region in a semiconductor layer and forming an array of trenches within the well region, the trenches extending from a top surface of the semiconductor layer into the well region. The method also includes forming an insulating layer on sidewalls and bottoms of the trenches and forming a conductive layer within the trenches, the conductive layer extending from the top surface of the semiconductor layer to the insulating layer at the bottoms of the trenches. The method further includes forming a first contact that provides a first terminal connecting to the well region at the top surface of the semiconductor layer, and forming second contacts that provide a second terminal connecting to top surfaces of the conductive layer within the trenches. The top surfaces of the conductive layer within the trenches may be coplanar with (i) a top surface of the well region and (ii) a top surface of a shallow trench isolation structure disposed surrounding the well region. The well region may have a first conductivity type and the semiconductor layer may have a second conductivity type, the semiconductor layer may include a buried layer having the first conductivity type, and the trenches may extend from the top surface of the semiconductor layer to the buried layer.

Forming the array of trenches may include forming a dielectric layer over the semiconductor layer, patterning a mask layer over the dielectric layer, and etching portions of the dielectric layer and underlying portions of the semiconductor layer exposed by the mask layer to form the array of trenches. Forming the well region may include performing an ion implantation self-aligned to the array of trenches.

Forming the insulating layer and forming the conductive layer may include forming a dielectric layer over the semiconductor layer, depositing one or more layers of insulating material over the dielectric layer and on the sidewalls and the bottoms of the trenches, filling a conductive material over the one or more layers of insulating material, and performing a planarization process to remove portions of the conductive material, portions of the one or more layers of insulating material and the dielectric layer, where remaining portions of the one or more layers of insulating material provide the insulating layer and remaining portions of the conductive material provide the conductive layer.

In some other examples, a semiconductor device includes a well region disposed in a semiconductor layer and an array of trenches disposed within the well region, the trenches extending from a top surface of the semiconductor layer into the well region. The semiconductor device also includes an insulating layer disposed on sidewalls and bottoms of the trenches and a conductive layer disposed within the trenches, the conductive layer extending from the top surface of the semiconductor layer to the insulating layer at the bottoms of the trenches. The semiconductor device further includes a first contact that provides a first terminal connecting to the well region at the top surface of the semiconductor layer, and second contacts that provide a second terminal connecting to top surfaces of the conductive layer within the trenches. The top surfaces of the conductive layer within the trenches may be coplanar with a top surface of the well region and/or a top surface of a shallow trench isolation structure disposed surrounding the well region.

While such examples may be expected to provide improvements, such as increased capacitance density or manufacturing flexibility, no particular result is a requirement of the present invention unless explicitly recited in a particular claim

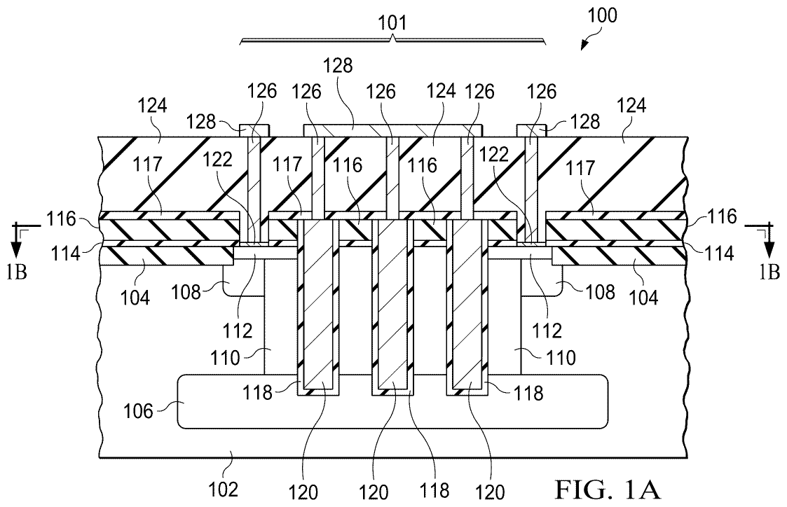

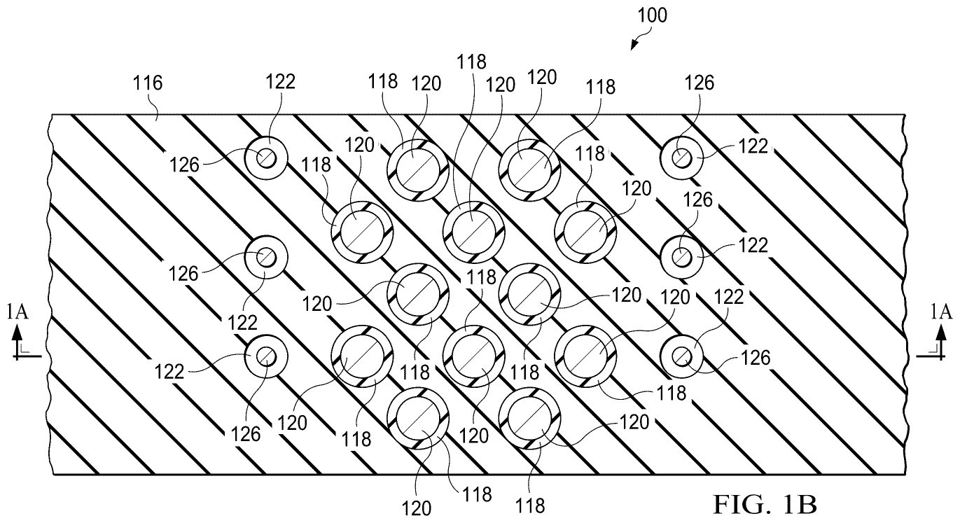

Referring now to FIGS. 1A and 1B, cross-sectional views of a semiconductor structure 100 with an integrated trench capacitor 101 is shown. The semiconductor structure 100 includes an epitaxial layer 102, STI structures 104, a buried layer 106, a shallow well region 108, a deep well region 110, doped regions 112, a pad oxide layer 114, dielectric layers 116 and 117, sidewall dielectric layer 118, conductive layer 120, silicide layers 122, pre-metal dielectric (PMD) layer 124, contacts 126, and interconnects 128. FIG. 1A shows a side cross-sectional view, while FIG. 1B shows a top-down cross-sectional view taken along the dielectric layer 116.

The buried layer 106, the shallow well region 108, the deep well region 110 and the doped regions 112 have a first conductivity type (e.g., n-type), while the epitaxial layer 102 has a second opposite conductivity type (e.g., p-type). The n-type buried layer 106 may also be referred to as NBL 106, the n-type shallow well region 108 may also be referred to as SNW 108, and the deep well region 110 may also be referred to as DNW 110. A “buried layer” is defined as a layer having a first doping characteristic, e.g. conductivity type, dopant type or dopant concentration, spaced apart from a top surface of the epitaxial layer 102 by another layer having a different second doping characteristic. In the present example, the epitaxial layer 102 is such a layer spacing the NBL 106 apart from the top surface of the epitaxial layer 102.

The epitaxial layer 102 may, for example, be formed over a bulk semiconductor wafer, a silicon-on-insulator (SOI) wafer, or other structure suitable. A base wafer may be p-type with a dopant concentration of about 10¹⁷ atoms/cm³ to 10¹⁸ atoms/cm³. Alternatively, the base wafer may be lightly doped, meaning the base wafer has an average dopant concentration below 10¹⁶ atoms/cm³. The epitaxial layer 102 may be silicon (Si) or another suitable semiconductor material.

The STI structures 104 may be formed in isolation trenches formed in the epitaxial layer 102. The STI structures 104 may be primarily silicon dioxide (SiO₂) or a SiO₂-based dielectric material that is formed by one or more CVD processes, possibly alternated with etch-back and/or chemical mechanical planarization (CMP) processes to provide complete filling of the isolation trenches. The STI structures 104 are planarized so that they do not extend over a top surface of the epitaxial layer 102.

The NBL 106 is formed within the epitaxial layer 102 by any suitable method, such as deep implantation or shallow implantation followed by epitaxial growth and diffusion. The NBL 106 may be about 2 micrometers (μm) to 10 μm thick, and may have a dopant concentration of about 10¹⁷ atoms/cm³ to 10¹⁸ atoms/cm³. The NBL 106 may be spaced apart from the top surface of the epitaxial layer 102 by a distance of about 6 μm to about 10 μm.

The SNW 108 is also formed within the epitaxial layer 102 by any suitable method, e.g. implantation and diffusion. The SNW 108 may be about 0.8 μm thick, and may have a dopant concentration of about 10¹⁷ atoms/cm³ to 10¹⁸ atoms/cm³.

The DNW 110 may be formed within the epitaxial layer 102 after trenches for the integrated trench capacitor 101 are formed. The trenches may have a depth of about 8 μm, and a diameter of about 1.1 μm or less. The DNW 110 may then be formed utilizing an angled ion implant process self-aligned to the trenches.

The DNW 110 may have a dopant concentration of about 10¹⁹ atoms/cm³ to 10²⁰ atoms/cm³. The DNW 110 extends from the top surface of the epitaxial layer 102 down to the NBL 106.

The doped regions 112 may be formed using a source/drain implant process contemporaneously with forming the source/drain regions in other areas of the epitaxial layer 102 not shown in FIG. 1. The doped regions 112 may be formed using one or more implant steps, with implant species including one or more of one or more of phosphorus and arsenic with an overall dose of between about 5×10¹³ cm⁻² and 4.5×10¹⁵ cm⁻² and an energy between about 2 keV and 80 keV. The doped regions 112 may be used for forming contacts to the bottom plate of the integrated trench capacitor 101, where the bottom plate includes the NBL 106, the SNW 108 and the DNW 110.

The pad oxide layer 114 may be an oxide material such as silicon dioxide (SiO₂) formed by a thermal oxidation process or a CVD process. The pad oxide layer 114 may be about 5 nm to 50 nm thick.

The dielectric layer 116 may be a nitride material such as silicon nitride (SiN), silicon oxynitride (SiON), etc. The dielectric layer 116 may be deposited utilizing any suitable deposition process, and may have a thickness of about 200 nm to 300 nm. The dielectric layer 116 may be formed prior to creating the trenches in which the integrated trench capacitor 101 will be formed, and prior to the ion implant process that forms the DNW 110. Following formation of the DNW 110, the sidewall dielectric layer 118, which provides an insulator for the integrated trench capacitor 101, is formed. The sidewall dielectric layer 118 may further provide a CMP stop layer when filling the conductive layer 120 in the trenches.

The sidewall dielectric layer 118 may comprise one or more layers of dielectric material, with a total thickness of about 15 nm to 50 nm. In some examples, the sidewall dielectric layer 118 includes an oxide-nitride-oxide (ONO) multi-layer. The ONO multi-layer may include a first oxide layer formed on sidewalls and bottoms of the trenches where the integrated trench capacitor 101 is formed, a nitride layer formed over the first oxide layer, and a second oxide layer formed over the nitride layer. The first oxide layer may have a thickness of about 5 nm to 10 nm, the nitride layer may have a thickness of about 5 nm to 15 nm, and the second oxide layer may have a thickness of about 5 nm to 10 nm.

The conductive layer 120 provides a top plate of the integrated trench capacitor 101, and may be formed of polysilicon or a metal material such as W, Al, etc. The dielectric layer 117, which may be or include silicon nitride, silicon oxynitride, or other suitable material, caps the conductive layer 120.

The silicide layers 122 may be formed using the dielectric layer 116 as a SIBLK layer, which is patterned using a SIBLK mask that is patterned over the structure exposing areas where the silicide layers 122 are to be formed. A metal layer which forms a metal silicide at temperatures consistent with typical semiconductor manufacturing process conditions is then deposited, and the structure is heated to form the silicide layers 122 in exposed areas of the epitaxial layer 102 (e.g., exposed portions of the doped regions 112 as illustrated in FIG. 1A). It should be noted that, if polysilicon is used as the conductive layer 120 material, then silicide layers 122 may also be formed over portions of the top surfaces of the conductive layer 120 in each of the trenches where the integrated trench capacitor structures is formed (e.g., by patterning the SIBLK mask layer over the dielectric layer 116 to have openings over the trenches where the integrated trench capacitor structures are formed). Unreacted metal is subsequently removed, e.g., in a wet stripping process.

After the silicide layers 122 are formed, the PMD layer 124 is formed. The PMD layer 124 may include a PMD liner (not specifically shown) formed over the structure. The PMD liner may be formed of SiN, SiON, SiO₂, etc. The main dielectric sublayer of the PMD layer 124 is formed over the PMD liner, if present. The main dielectric sublayer of the PMD layer 124 may be formed by one or more dielectric deposition processes, including a PECVD process using TEOS, a high-density plasma (HDP) process, or a high aspect ratio process (HARP) using TEOS and ozone. The PMD layer 124 may be planarized by an oxide CMP process.

The contacts 126 may be formed by patterning and etching contact holes through the PMD layer 124 (and the PMD liner, if present) to expose portions of the silicide layers 122 and the conductive layer 120 formed in each of the trenches. As discussed above, in examples where the conductive layer 120 is polysilicon, then the silicide layers 122 may also be formed over at least a portion of the conductive layer 120 in each of the trenches where the integrated trench capacitor structures are formed. In examples in which the conductive layer 120 is metal, then the silicide layers 122 need not be formed over the conductive layer 120. The contacts 126 are filled in the contact holes, in some examples, by sputtering titanium or another suitable material to form a metal adhesion layer, followed by forming a titanium nitride (TiN) or other suitable diffusion barrier using reactive sputtering or an ALD process. A tungsten core may then be formed by an MOCVD process using tungsten hexafluoride (WF₆) reduced by silane initially and hydrogen after a layer of tungsten is formed on the TiN diffusion barrier. The tungsten, TiN, and titanium may be subsequently removed from a top surface of the PMD layer 124 by a plasma etch process, a tungsten CMP process, or a combination of both, leaving the contacts 126 extending to the top surface of the PMD layer 124. In some examples, the contacts 126 may be formed by a selective tungsten deposition process which fills the holes with tungsten from the bottom up, forming the contacts 126 with a uniform composition of tungsten.

The interconnects 128 are then formed over the PMD layer 124 and connecting to the contacts 126. As shown, the contacts 126 formed to the conductive layer 120 in each of the trenches of the integrated trench capacitor 101, and are connected together with one of the interconnects 128. In some examples, the interconnects 128 have an etched aluminum structure, and may be formed by depositing an adhesion layer, an aluminum layer and an anti-reflection layer, and forming an etch mask followed by an RIE process to etch the anti-reflection layer, the aluminum layer and the adhesion layer where exposed by the etch mask, and subsequently removing the etch mask. In other examples, the interconnects 128 have a damascene structure, and may be formed by forming an inter-metal dielectric layer (not shown) on the PMD layer 124 and etching interconnect trenches through the IMD layer to expose the contacts 126. A barrier liner (not shown) may be formed by sputtering tantalum onto the IMD layer, the PMD layer 124 and the contacts 126 which are exposed, and then forming tantalum nitride (TaN) on the sputtered tantalum by an ALD process. A copper fill metal may be formed by sputtering a seed layer (not shown) of copper on the barrier line, and electroplating copper on the seed layer to fill the interconnect trenches. The copper and barrier liner metal are subsequently removed from a top surface of the IMD layer by a copper CMP process. In other examples, the interconnects 128 have a plated structure, and may be formed by sputtering an adhesion layer, containing titanium, on the PMD layer 124 and the contacts 126, followed by sputtering a seed layer of copper on the adhesion layer. A plating mask is formed on the seed layer that exposes areas for the interconnects 128. The interconnects 128 are then formed by electroplating copper on the seed layer where exposed by the plating mask. The plating mask is removed, and the seed layer and the adhesion layer are removed by wet etching between the interconnects 128.

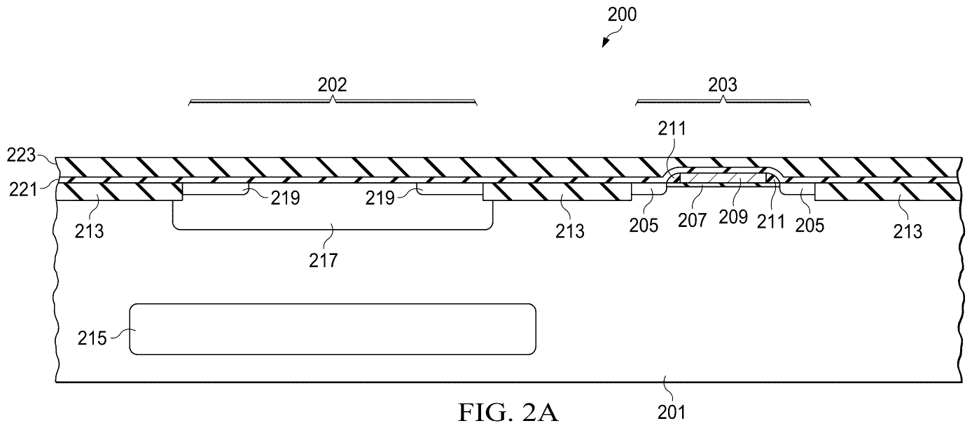

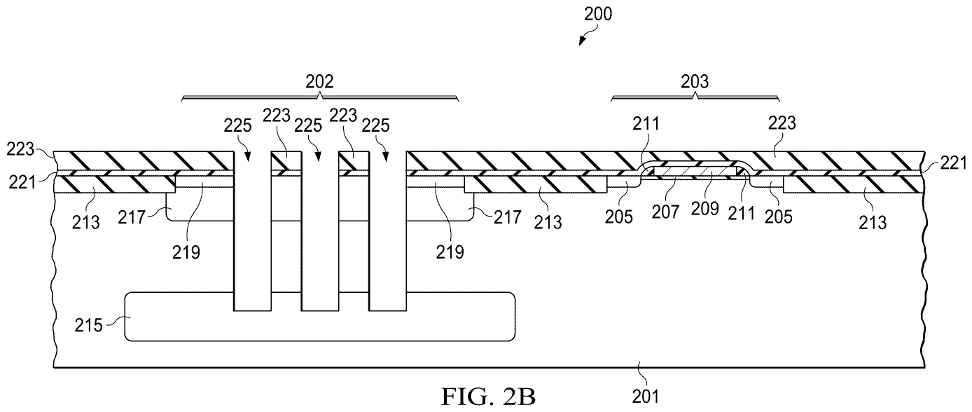

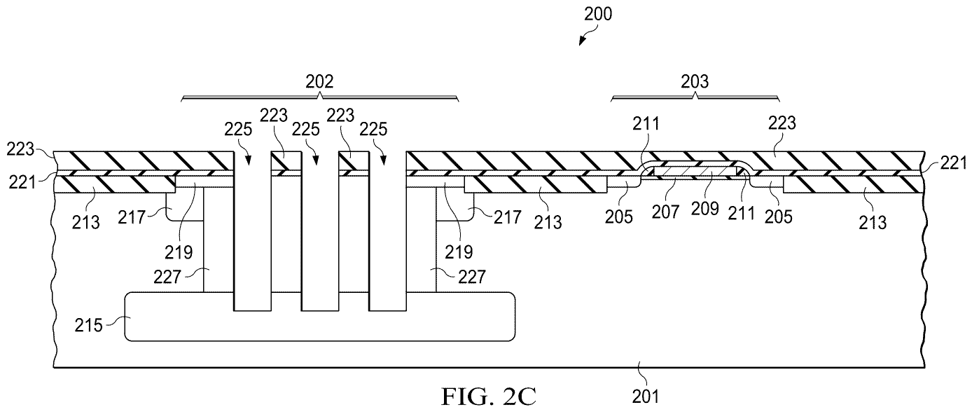

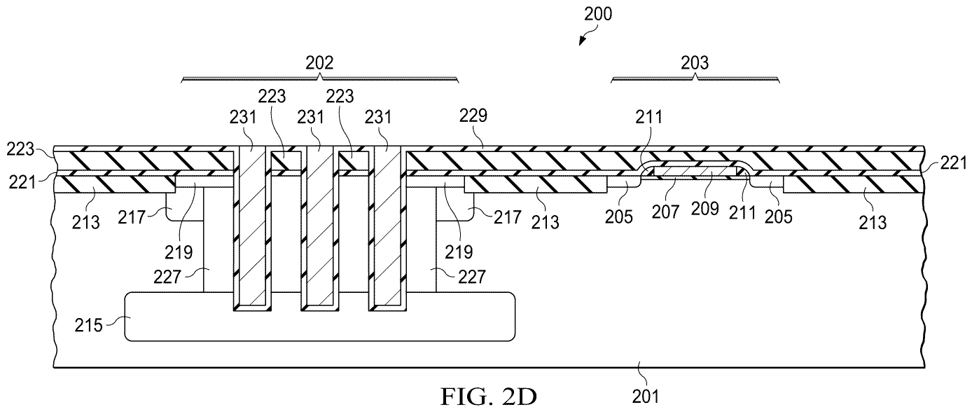

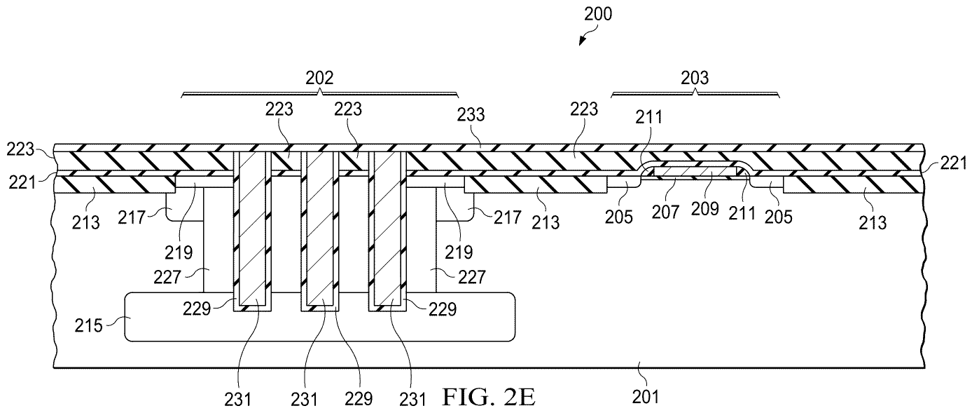

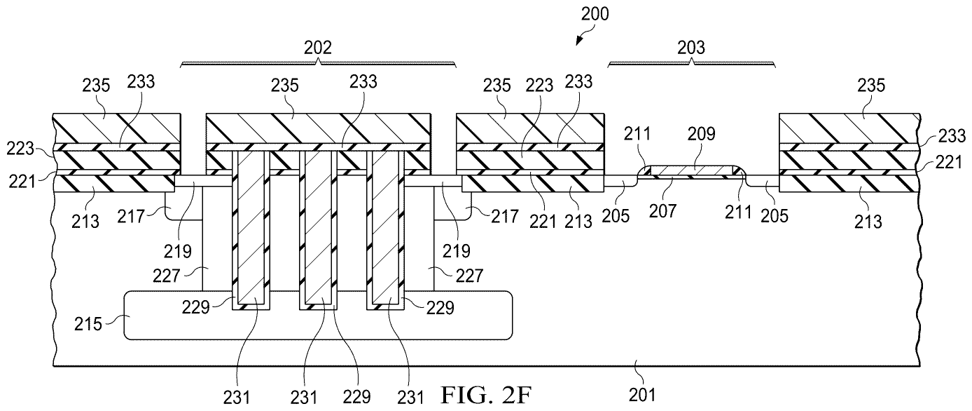

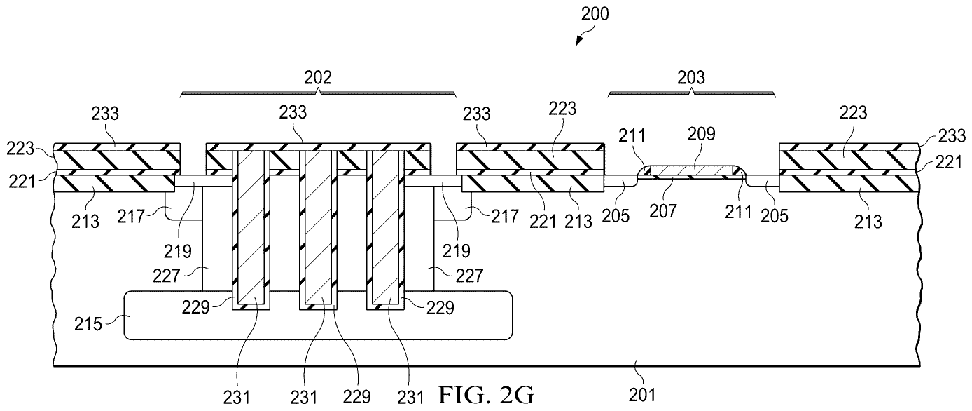

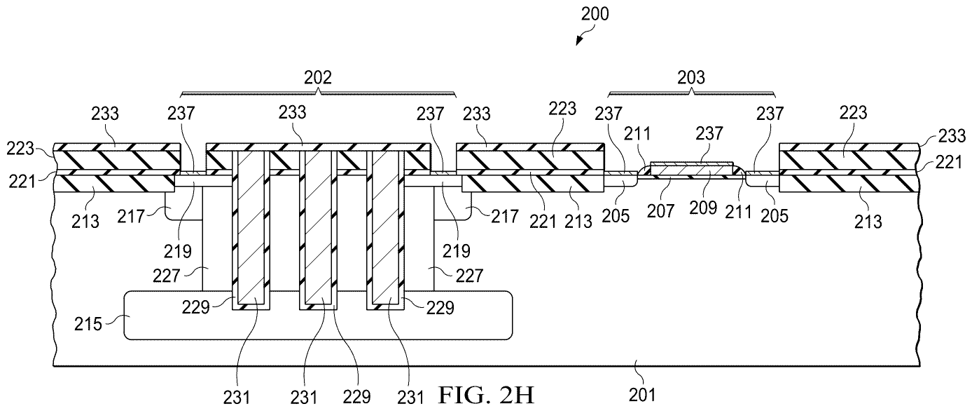

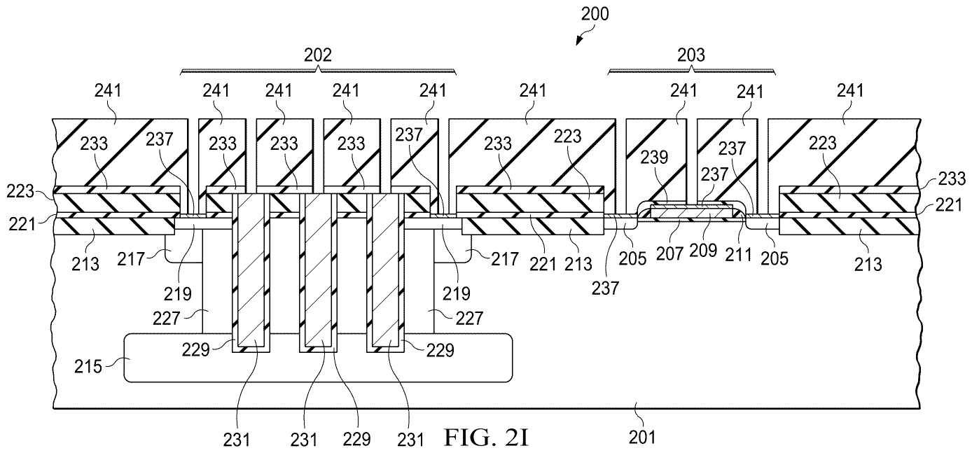

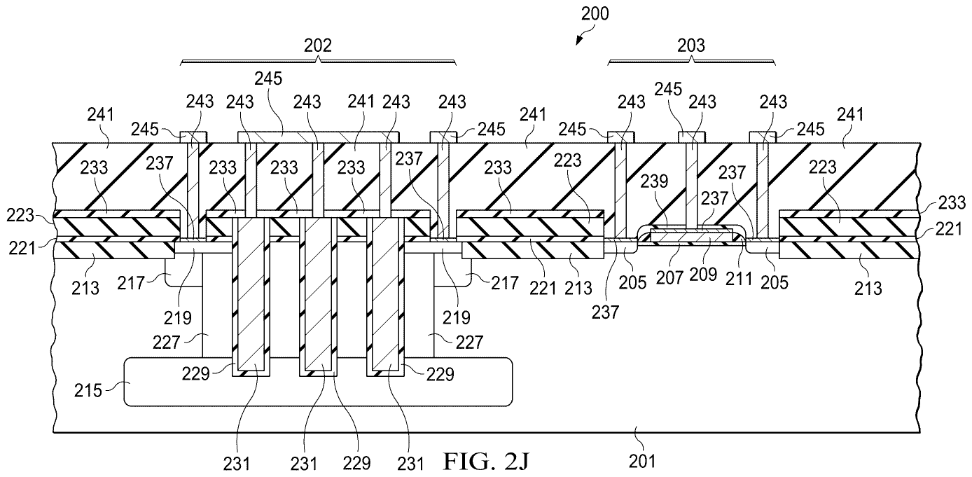

Referring now to FIGS. 2A-2J, cross-sectional views of a process flow for forming a semiconductor device with integrated trench capacitor structures analogous to the semiconductor structure 100 are shown. These figures provide an example of forming the integrated trench capacitor structures after forming transistors in a substrate.

FIG. 2A shows a semiconductor structure 200, e.g. an integrated circuit, in which a transistor structure has been formed over a substrate including a p-type epitaxial layer 201, and an integrated trench capacitor 202 is to be formed. An example transistor 203includes n-type source/drain regions 205, gate dielectric layer 207, gate electrode 209 and gate spacers 211. STI structures 213 provide lateral isolation between the transistor 203 and the trench capacitor 202. NBL 215 and SNW 217 have been formed in an earlier stage of processing, and n-type doped regions 219 have been formed optionally coincident with forming the source/drain regions 205. Pad oxide layer 221 and dielectric layer 223 have been formed as previously described. The epitaxial layer 201, which may be regarded as a semiconductor substrate or semiconductor layer, has a top surface coincident with a top surface of the doped regions 219 or the STI structures 213. In some examples, the dielectric layer 223 comprises silicon nitride, and may be referred to without limitation as silicon nitride layer 223, or for brevity nitride layer 223, in the description below. In other examples, however, the dielectric layer 223 may be an oxide material or other suitable dielectric material.

FIG. 2B shows the semiconductor structure 200 of FIG. 2A following formation of trenches 225. The trenches 225 may be formed by patterning a mask layer (not shown) over the nitride layer 223, and etching exposed portions of the nitride layer 223, the pad oxide layer 221 and the p-type epitaxial layer 201 through the SNW 217 and down into the NBL 215. Each of the trenches 225 may have a depth of about 8 μm and a diameter of about 1.1 μm or less.

FIG. 2C shows the semiconductor structure 200 of FIG. 2B following formation of DNW 227. The DNW 227 may be formed using a self-aligned angled deep n-well implant using an implant mask, followed by ashing and cleaning to remove the implant mask. This may be followed by formation and removal of a pad oxide layer (not shown) to clean the damaged surface, which may be followed by a source/drain anneal.

FIG. 2D shows the semiconductor structure 200 of FIG. 2C following formation of dielectric layer 229 and conductive fill layer 231. The dielectric layer 229 provides an insulator between the bottom and top plates of the integrated trench capacitor 202, where the NBL 215, SNW 217 and DNW 227 provide the bottom plate of the integrated trench capacitor 202 and where the conductive fill layer 231 provides the top plate of the integrated trench capacitor 202. The dielectric layer 229 may include an ONO multi-layer. The conductive fill layer 231 may include a metal material such as W, Al, etc. The dielectric layer 229 is deposited on sidewalls and bottoms of the trenches 225 and over the top surface of the nitride layer 223. The conductive fill layer 231 is then deposited over the dielectric layer 229.

FIG. 2E shows the semiconductor structure 200 of FIG. 2D following planarization (e.g., using CMP or other suitable processing) which removes portions of the dielectric layer 229 formed on the top surface of the nitride layer 223. Following the planarization processing, a dielectric layer 233 is formed over the structure. The dielectric layer 233 may be a same or different material than the dielectric layer 223. In some examples, the dielectric layer 233 is a same material the dielectric layer 223, and in some such examples may be a silicon nitride layer when the dielectric layer 223 comprises silicon nitride. The dielectric layer 233 may be referred to without limitation as silicon nitride layer 233, or for brevity nitride layer 233, in the continued discussion. The nitride layer 233 may have a thickness of approximately 10 nm. The nitride layer 233 may protect the integrated trench capacitor 202 during subsequent processing steps, and may act as a SIBLK layer that covers the area where the trenches 225 are formed.

FIG. 2F shows the semiconductor structure 200 of FIG. 2E following patterning of a SIBLK mask layer 235, e.g., a photoresist layer, over the structure, and following etching of portions of the nitride layers 233 and 223 and the pad oxide layer 221 exposed by the patterned SIBLK mask layer 235. The nitride layers 233 and 223 may be etched using a plasma etch that stops on the pad oxide layer 221, and then the pad layer 221 may be etched to expose semiconductor surfaces of the n-type doped regions 219, the source/drain regions 205 and the gate electrode 209.

FIG. 2G shows the semiconductor structure 200 of FIG. 2F following removal of the SIBLK layer 235, e.g., by an oxygen ash. A pre-sputter clean process may also be performed using hydrofluoric acid (HF).

FIG. 2H shows the semiconductor structure 200 of FIG. 2G following formation of silicide layers 237. The silicide layers 237 may be formed using a metal sputter and silicide formation (e.g., heating the structure for approximately 30 seconds at about 500° C., followed by a silicide strip and silicide anneal for approximately 30 seconds at about 870° C.). The silicide layers 237 may include cobalt monosilicide (CoSi).

FIG. 2I shows the semiconductor structure 200 of FIG. 2H following formation of a PMD liner 239 and PMD layer 241, and following formation of contact holes or trenches through the PMD layer 241 which expose surfaces of the silicide layers 237 and the conductive fill layer 231 within each of the trenches 225. The PMD liner 239 may have a thickness of about 35 nm, and the PMD layer 241 may have a thickness of about 600 nm to 700 nm. The PMD layer 241 may then be planarized using CMP or other suitable processing, followed by patterning a mask layer over the structure and etching contact holes which stop at the silicide layers 237 and the conductive fill layer 231 in each of the trenches 225.

FIG. 2J shows the semiconductor structure 200 of FIG. 2I following formation of contacts 243 in the contact holes formed in the PMD layer 241, and following formation of interconnects 245. As shown, one of the interconnects 245 connects the contacts 243 formed to the conductive fill layer 231 in each of the trenches 225.

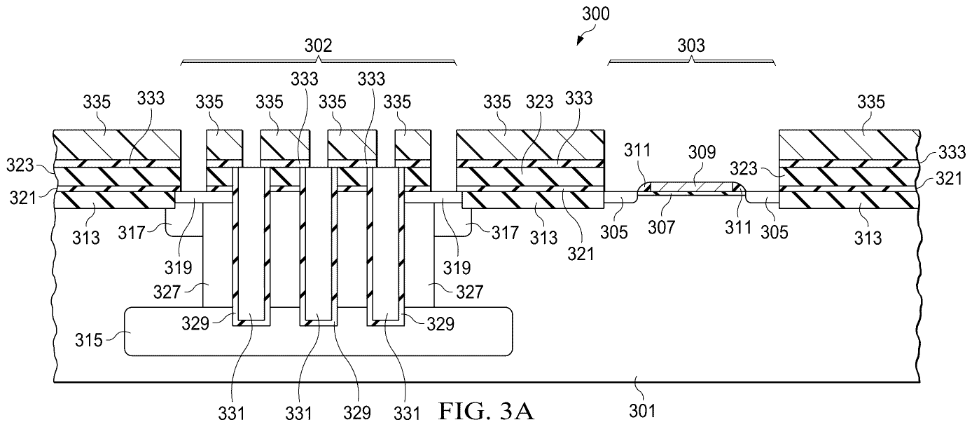

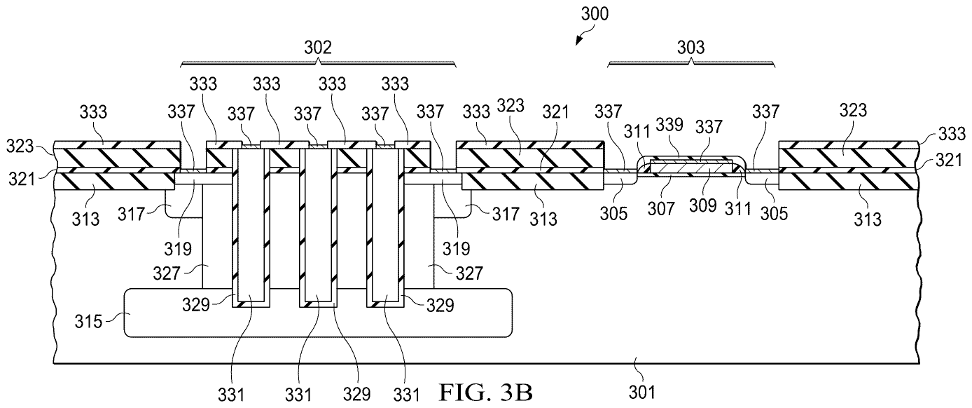

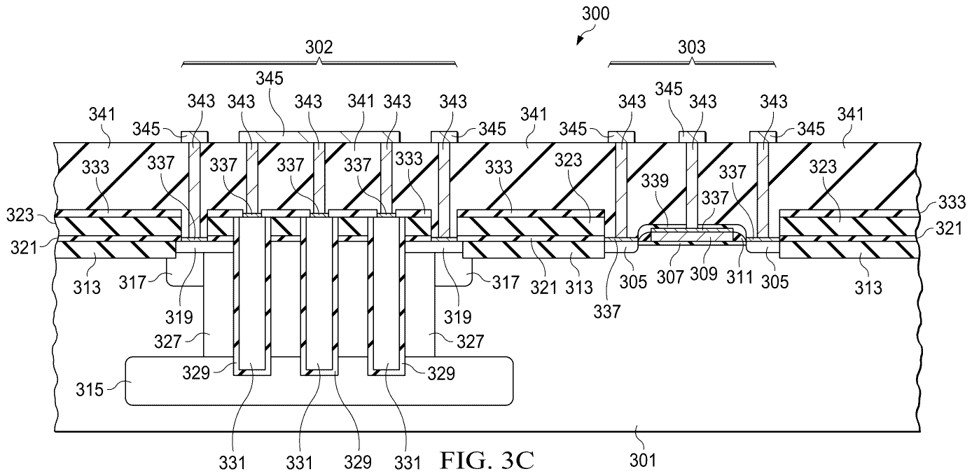

As discussed above, FIGS. 2A-2J show a process flow for forming the integrated trench capacitor 202 in semiconductor structure 200 where the conductive fill layer 231 providing the top plates of the integrated trench capacitor 202 is a metal material. FIGS. 3A-3C show cross-sectional views of a portion of a process flow for forming an integrated trench capacitor 302 in a semiconductor structure 300 where the top plates of the integrated trench capacitor 302 are polysilicon or similar semiconductor materials, and in which a transistor 303 has already been formed.

FIG. 3A shows a cross-sectional view of the semiconductor structure 300 which, similar to the semiconductor structure 200 as shown in FIG. 2F, includes p-type epitaxial layer 301, sometimes referred to as a substrate 301, and a transistor 303 and a partially-formed integrated trench capacitor 302 formed thereover. The semiconductor structure 300 further includes n-type source/drain regions 305, gate dielectric layer 307, gate electrode 309 and gate spacers 311 of the transistor 303, and STI structures 313 that provide electrical isolation between the transistor 303 and the integrated trench capacitor 302. Features of the integrated trench capacitor 302 already formed include NBL 315, SNW 317, n-type doped regions 319, pad oxide layer 321, nitride layer 323, DNW 327, dielectric layers 329, conductive fill layer 331, and silicon nitride layer 333. SIBLK mask layer 335 has been formed over the silicon nitride layer 333 and patterned. One or more of the described features of the semiconductor structure 300 may be formed in a manner similar to that described above with respect to corresponding features of the semiconductor structure 200.

The semiconductor structure 300 further includes a conductive fill layer 331 comprising polysilicon (whereas the conductive fill layer 231 in the process flow of FIGS. 2A-2J comprises a metal). The SIBLK mask layer 335 is therefore patterned with openings over the silicon nitride layer 333, which acts as a SIBLK layer, over the top surface of the conductive fill layer 331, in addition to openings over the n-type source/drain regions 305, the gate electrode 309 and the n-type doped regions 319. In the view of FIG. 3A, the nitride layers 323, 333 and pad oxide layer 321 have been removed where exposed to the openings in the SIBLK mask layer 335.

FIG. 3B shows a cross-sectional view of the semiconductor structure 300 following formation of silicide layers 337 on the exposed semiconductor (e.g., Si) surfaces of the n-type source/drain regions 305, the gate electrode 309, the n-type doped regions 319 and the conductive fill layer 331. The silicide layers 337 may be formed using similar processing as that described above with respect to formation of the silicide layers 237.

FIG. 3C shows a cross-sectional view of the semiconductor structure 300 following formation of PMD liner 339, PMD layer 341, contacts 343 and interconnects 345, which may be formed using processing similar to that described above with respect to formation of the PMD liner 239, the PMD layer 241, the contacts 243 and the interconnects 245, respectively.

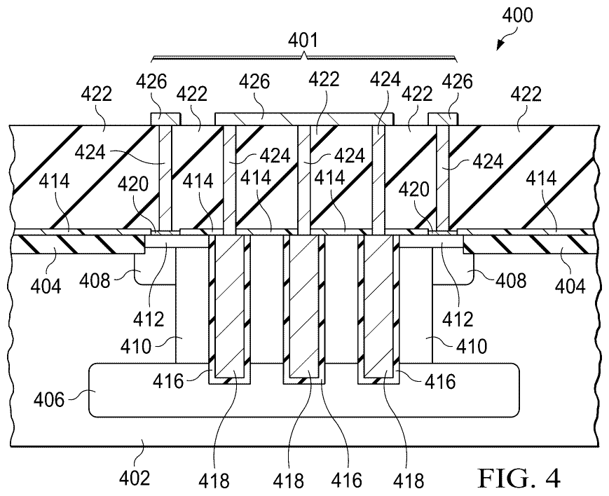

FIGS. 1A-3C have shown different examples in which a dielectric layer (e.g., dielectric layer 116, nitride layer 223, and nitride layer 323) is formed over a top surface of a semiconductor substrate or epitaxial layer (e.g., epitaxial layer 101, p-type epitaxial layer 201, and p-type epitaxial layer 301), and where integrated trench capacitor structures are formed through such dielectric layers (e.g., extending from a top surface of the dielectric layers down to buried layers within the epitaxial layer). In these examples, the integrated trench capacitor structures thus have top surfaces which are above the top surface of the epitaxial layer and STI structures (e.g., STI structures 104, STI structures 213, and STI structure 313) formed within the epitaxial layer. In some examples, the nitride layers overlying the integrated trench capacitor structures are a consequence of the presence of a transistor or similar device on the substrate prior to forming the integrated trench capacitor structures. In other examples, the integrated trench capacitor structures may be formed before forming transistors on the same substrate. In such examples, the top surfaces of the integrated trench capacitor structures may be nearly coplanar with a top surface of the epitaxial layer as well as the STI structures, or coplanar with a top surface of a pad oxide or SIBLK layer over the epitaxial layer. FIG. 4 shows an example semiconductor structure 400 with such an arrangement.

Referring now to FIG. 4, a cross-sectional view of a semiconductor structure 400 with an integrated trench capacitor 401 is shown. The semiconductor structure 400 includes an epitaxial layer 402, sometimes referred to as a substrate 402, STI structures 404, a buried layer 406, a shallow well region 408, a deep well region 410, doped regions 412, an optional SIBLK (e.g., silicon oxide or silicon nitride) layer 414, dielectric layer 416, conductive fill layer 418, silicide layers 420, PMD layer 422, contacts 424 and interconnects 426. The buried layer 406, the shallow well region 408, the deep well region 410 and the doped regions 412 have a first conductivity type (e.g., n-type), while the epitaxial layer 402 has a second opposite conductivity type (e.g., p-type). The n-type buried layer 406 may also be referred to as NBL 406, the n-type shallow well region 408 may also be referred to as SNW 408, and the deep well region 410 may also be referred to as DNW 410.

The epitaxial layer 402, the STI structures 404, the NBL 406, the SNW 408, the DNW 410, the doped regions 412 may be formed in a manner similar to that described above with respect to the epitaxial layer 102, the STI structures 104, the NBL 106, the SNW 108, the DNW 110, and the doped regions 112, respectively.

To form the dielectric layer 416 and the conductive layer 418, a sacrificial hard mask layer, e.g., silicon nitride, (not shown) may be deposited over the structure and patterned. This nitride layer may be formed prior to creating the trenches where the integrated trench capacitor structure 401 will be formed, and prior to the ion implant process that forms the DNW 410. The dielectric layer 416, like the dielectric layer 118, may include an ONO multi-layer. The dielectric layer 416 is deposited over the nitride layer (not shown) and on sidewalls and bottoms of the trenches. The conductive fill layer 418 is deposited over the dielectric layer 416, followed by planarization (e.g., using CMP) which stops at the SIBLK layer 414, thus removing the nitride layer. The dielectric layer 416 provides an insulator between bottom and top plates of the integrated trench capacitor 401, where the NBL 406, the SNW 408 and the DNW 410 provide the bottom plate of the integrated trench capacitor 401 and the conductive layer 418 provides the top plate of the integrated trench capacitor 401. The conductive layer 418 may be formed of polysilicon or a metal material such as W or other refractory metal.

The silicide layers 420, the PMD layer 422, the contacts 424 and the interconnects 426 are then formed using processing similar to that described above with respect to the silicide layers 122, the PMD layer 124, the contacts 126 and the interconnects 128, respectively, where the SIBLK layer 414 is used for patterning openings where the silicide layers 420 are to be formed. Although FIG. 4 shows an example where the SIBLK layer 414 remains in the final structure, the SIBLK layer 414 may optionally be removed after the silicide layers 420 are formed.

As shown in FIG. 4, in the semiconductor structure 400 the top surfaces of the integrated trench capacitor structures (e.g., the top surface of the conductive layer 418 filled in the trenches) are coplanar with the top surface of the epitaxial layer 402 and the STI structures 404 formed therein. This is different than the semiconductor structure 100, where the top surface of the integrated trench capacitor structures are above the top surface of the epitaxial layer 102 and the STI structures 104 formed therein (e.g., the top surface of the conductive layer 120 filled in the trenches is coplanar with a top surface of the dielectric layer 116 that is formed over the epitaxial layer 102). In both the semiconductor structure 100 and the semiconductor structure 400, the integrated trench capacitor structures are formed after the STI structures 104 and the STI structures 404, with the result that the top terminals or plates of the integrated trench capacitor structures are inherently isolated from the bottom terminals or plates of the integrated trench capacitor structures.

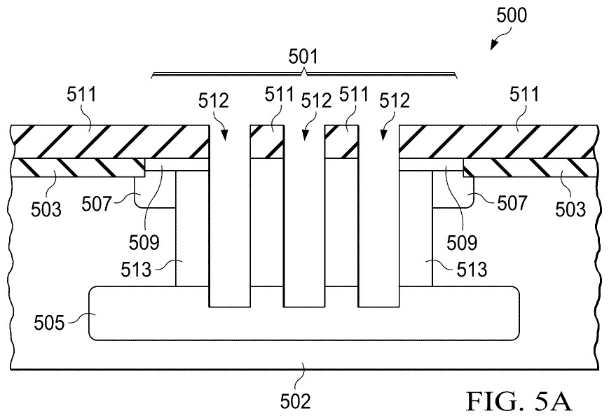

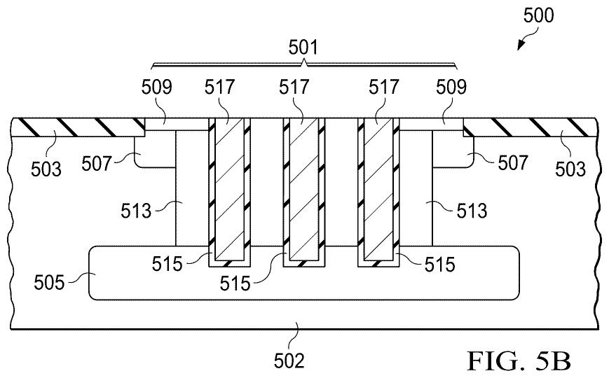

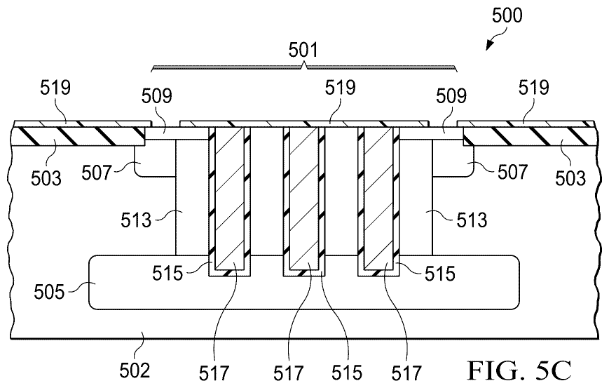

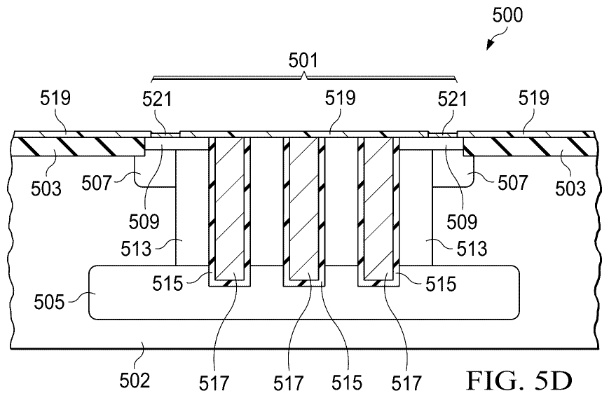

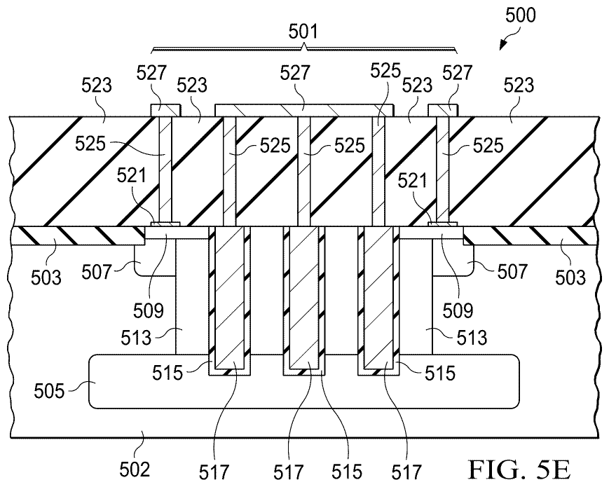

Referring now to FIGS. 5A-5E, cross-sectional views of a process flow for forming a semiconductor device with integrated trench capacitor structures are shown.

FIG. 5A shows a semiconductor structure 500 in which an integrated trench capacitor 501 is to be formed. The semiconductor structure 500 includes p-type epitaxial layer 502, sometimes referred to as substrate 502, STI structures 503, NBL 505, SNW 507, n-type doped regions 509, nitride layer 511, and DNW 513. The semiconductor structure 500 is shown with trenches 512 formed therein, which may be formed using processing similar to that described above with respect to FIG. 2C by patterning a mask layer over the nitride layer 511 and etching through exposed portions of the nitride layer 511 and the p-type epitaxial layer 502 down to the NBL 505. The p-type epitaxial layer 502, the STI structures 503, the NBL 505, the SNW 507, the n-type doped regions 509, the nitride layer 511 and the DNW 513 may be formed using similar processing as that described above with respect to the p-type epitaxial layer 201, the STI structures 213, the NBL 215, the SNW 217, the n-type doped regions 219, the nitride layer 223 and the DNW 227, respectively.

FIG. 5B shows the semiconductor structure 500 of FIG. 5A following formation of dielectric layer 515 on sidewalls and bottoms of the trenches 512, and formation of conductive fill layer 517 over the dielectric layer 515. The dielectric layer 515 and the conductive fill layer 517 may be formed using processing similar to that described above with respect to formation of the dielectric layer 229 and the conductive fill layer 231, respectively, though planarization removes the nitride layer 511 (e.g., the planarization continues until reaching a top surface of the p-type epitaxial layer 502 or a pad oxide layer formed on the top surface of the p-type epitaxial layer 502, not explicitly shown).

At the stage of manufacturing represented by FIG. 5B, transistors or similar components may be formed over the substrate 502. When formed from W or other refractory metal, the conductive fill layer 517 is robust against the thermal processing typically used to form such components. Thus, the conductive fill layer 517 may optionally remain exposed during such processing. Furthermore, the n-type doped regions 509, shown as already formed in FIG. 5B, may optionally be formed concurrently with an NSD implant of source/drain regions of other components. After forming the other components, manufacturing of the integrated trench capacitor may resume at FIG. 5C.

FIG. 5C shows the semiconductor structure 500 of FIG. 5B following patterning of a SIBLK layer 519 over the structure, exposing portions of the n-type doped regions 509 connecting to the bottom plate of the integrated trench capacitor 501 (the NBL 505, the SNW 507 and the DNW 513). In the semiconductor structure 500, the conductive fill layer 517 is assumed to be formed of a metal material such as W, Al, etc. Thus, the SIBLK layer 519 covers the area where the trenches 512 are formed as silicide layers are not needed to form contacts to the conductive fill layer 517.

FIG. 5D shows the semiconductor structure 500 of FIG. 5C following formation of silicide layers 521 on the exposed portions of the n-type doped regions 509. The silicide layers 521 may be formed using processing similar to that described above with respect to formation of silicide layers 237, and may be formed concurrently with silicide formation on transistor features.

FIG. 5E shows the semiconductor structure 500 of FIG. 5D following removal of the SIBLK layer 519, and following formation of PMD layer 523, contacts 525 and interconnects 527. The PMD layer 523, the contacts 525 and the interconnects 527 may be formed using processing similar to that described above with respect to formation of the PMD layer 241, the contacts 243 and the interconnects 245, respectively.

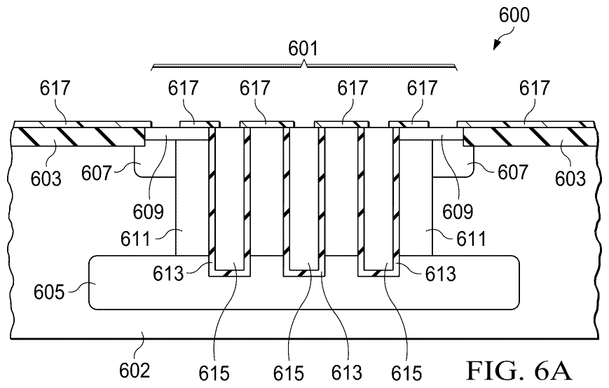

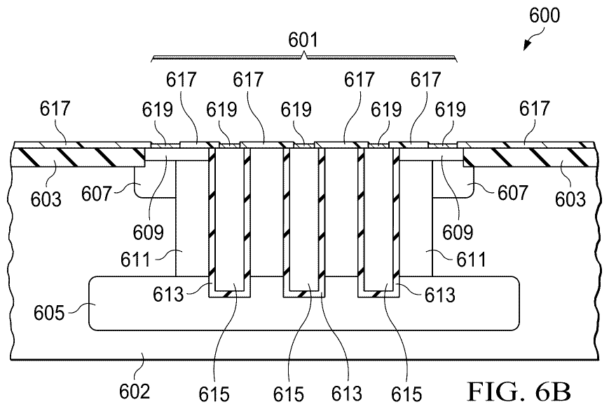

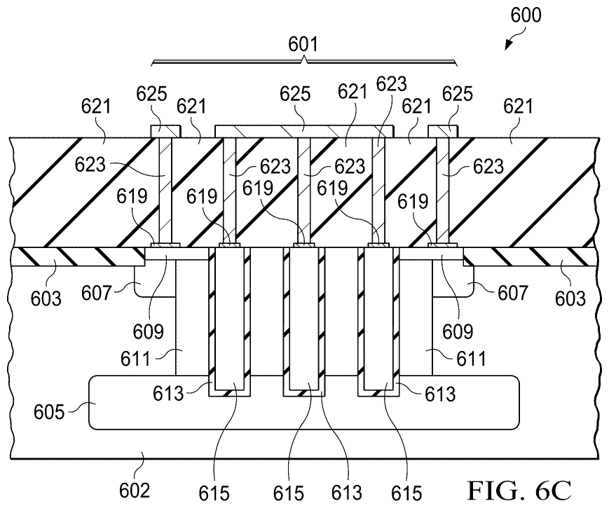

As discussed above, FIGS. 5A-5E shows a process flow for forming the integrated trench capacitor 501 in semiconductor structure 500 where the conductive fill layer 517 providing the top plate of the integrated trench capacitor 501 includes a metal material. FIGS. 6A-6C show cross-sectional views of a process flow for forming an integrated trench capacitor 601 in a semiconductor structure 600 over a p-type epitaxial layer 602, or substrate 602, where the top plate of the integrated trench capacitor 601 includes polysilicon. The integrated trench capacitor 601 may also be formed before forming transistors or similar components over the substrate 602.

FIG. 6A shows a cross-sectional view of the semiconductor structure 600, which similar to the semiconductor structure 500 as shown in FIG. 5C, includes STI structures 603, NBL 605, SNW 607, n-type doped regions 609, DNW 611, dielectric layer 613, conductive fill layer 615 and SIBLK layer 617. The p-type epitaxial layer 602, the STI structures 603, the NBL 605, the SNW 607, the n-type doped regions 609, the DNW 611, the dielectric layer 613, the conductive fill layer 615 and the SIBLK layer 617 may be formed using processing similar to that described above with respect to the p-type epitaxial layer 502, the STI structures 503, the NBL 505, the SNW 507, the n-type doped regions 509, the DNW 513, the dielectric layer 515, the conductive fill layer 517 and the SIBLK layer 519, respectively. In the semiconductor structure 600, however, the conductive fill layer 615 comprises polysilicon (whereas the conductive fill layer 517 in the process flow of FIGS. 5A-5E is metal). As a result, the SIBLK layer 617 is patterned with openings that expose portions of the top surface of the conductive fill layer 615 filled in each of the trenches, in addition to exposing surfaces of the n-type doped regions 609.

At the stage of manufacturing represented by FIG. 6A, transistors or similar components may be formed over the substrate 602. Exposed polysilicon of the conductive fill layer 617 may oxidize during some thermal processes associated with transistor formation, but any such oxidation may be removed by a subsequent contact etch. Furthermore, the n-type doped regions 609, shown as already formed in FIG. 6A, may optionally be formed concurrently with an NSD implant of source/drain regions of other components. After forming the other components, manufacturing of the integrated trench capacitor may resume at FIG. 6B.

FIG. 6B shows a cross-sectional view of the semiconductor structure 600 of FIG. 6A following formation of silicide layers 619 on the exposed semiconductor (e.g., Si) surfaces of the n-type doped regions 609 and the conductive fill layer 615. The silicide layers 619 may be formed using similar processing as that described above with respect to formation of the silicide layers 521, and may be formed concurrently with silicide formation on transistor features.

FIG. 6C shows a cross-sectional view of the semiconductor structure 600 of FIG. 6B following an optional removal of the SIBLK layer 617 and formation of PMD layer 621, contacts 623 and interconnects 625. The PMD layer 621, the contacts 623 and the interconnects 6245 may be formed using processing similar to that described above with respect to formation of the PMD layer 523, the contacts 525 and the interconnects 527, respectively.

In addition, while in accordance with illustrated implementations, various features or components have been shown as having particular arrangements or configurations, other arrangements and configurations are possible. Moreover, aspects of the present technology described in the context of example implementations may be combined or eliminated in other implementations. Thus, the breadth and scope of the description is not limited by any of the above-described implementations.

What is claimed is:

1. A method of fabricating a semiconductor device, comprising:
forming a well region in a semiconductor layer;
forming a dielectric layer over the well region that extends upward from a top surface of the semiconductor layer;
forming an array of trenches within the dielectric layer and the well region, the trenches extending from a top surface of the dielectric layer into the well region;
forming an insulating layer on sidewalls and bottoms of the trenches;
forming a conductive layer within the trenches, the conductive layer extending from the top surface of the dielectric layer to the insulating layer at the bottoms of the trenches;
forming a first contact that provides a first terminal connecting to the well region at the top surface of the semiconductor layer; and
forming second contacts that provide a second terminal connecting to top surfaces of the conductive layer within the trenches.

2. The method of claim 1, wherein forming the array of trenches comprises:
patterning a mask layer over the dielectric layer; and
etching portions of the dielectric layer and underlying portions of the semiconductor layer exposed by the mask layer to form the array of trenches.

3. The method of claim 2, wherein forming the well region comprises performing an angled ion implantation self-aligned to the array of trenches.

4. The method of claim 1, wherein forming the insulating layer and forming the conductive layer comprise:
depositing one or more layers of insulating material over the dielectric layer and on the sidewalls and the bottoms of the trenches;
filling a conductive material over the one or more layers of insulating material; and
performing a planarization process to remove portions of the conductive material, the one or more layers of insulating material and the dielectric layer, wherein remaining portions of the one or more layers of insulating material provide the insulating layer and remaining portions of the conductive material provide the conductive layer.

5. The method of claim 1, wherein the top surfaces of the conductive layer within the trenches are coplanar with the top surface of the dielectric layer formed over the well region.

6. The method of claim 1, wherein the well region has a first conductivity type and the semiconductor layer has a second conductivity type, wherein the semiconductor layer comprises a buried layer having the first conductivity type, and wherein the trenches extend from the top surface of the dielectric layer and through the well region to the buried layer.

7. The method of claim 1, wherein the conductive layer comprises metal electrodes.

8. The method of claim 1, wherein the conductive layer comprises polysilicon.

9. A semiconductor device, comprising:
a well region disposed in a semiconductor layer;
a dielectric layer disposed over the well region and extending above a top surface of the semiconductor layer;
an array of trenches disposed within the dielectric layer and the well region, the trenches extending from a top surface of the dielectric layer into the well region;
an insulating layer disposed on sidewalls and bottoms of the trenches;
a conductive layer disposed within the trenches, the conductive layer extending from the top surface of the dielectric layer to the insulating layer at the bottoms of the trenches;
a first contact that provides a first terminal connecting to the well region at the top surface of the semiconductor layer; and
second contacts that provide a second terminal connecting to top surfaces of the conductive layer within the trenches.

10. The semiconductor device of claim 9, wherein the top surfaces of the conductive layer within the trenches are coplanar with the top surface of the dielectric layer formed over the well region.

11. The semiconductor device of claim 9, wherein the well region has a first conductivity type and the semiconductor layer has a second conductivity type, wherein the semiconductor layer comprises a buried layer having the first conductivity type, and wherein the trenches extend from the top surface of the dielectric layer and through the well region to the buried layer.

12. The semiconductor device of claim 9, wherein the conductive layer comprises metal electrodes.

13. The semiconductor device of claim 9, wherein the conductive layer comprises polysilicon.

14. The semiconductor device of claim 9, wherein the dielectric layer comprises a nitride material.

15. A method of fabricating a semiconductor device, comprising:
forming a well region in a semiconductor layer;
forming an array of trenches within the well region, the trenches extending from a top surface of the semiconductor layer into the well region;
forming an insulating layer on sidewalls and bottoms of the trenches;
forming a conductive layer within the trenches, the conductive layer extending from the top surface of the semiconductor layer to the insulating layer at the bottoms of the trenches;
forming a first contact that provides a first terminal connecting to the well region at the top surface of the semiconductor layer; and
forming second contacts that provide a second terminal connecting to top surfaces of the conductive layer within the trenches.

16. The method of claim 15, wherein forming the array of trenches comprises:
forming a dielectric layer over the semiconductor layer;
patterning a mask layer over the dielectric layer; and
etching portions of the dielectric layer and underlying portions of the semiconductor layer exposed by the mask layer to form the array of trenches.

17. The method of claim 16, wherein forming the well region comprises performing an ion implantation self-aligned to the array of trenches.

18. The method of claim 15, wherein forming the insulating layer and forming the conductive layer comprise:
forming a dielectric layer over the semiconductor layer;
depositing one or more layers of insulating material over the dielectric layer and on the sidewalls and the bottoms of the trenches;
filling a conductive material over the one or more layers of insulating material; and
performing a planarization process to remove portions of the conductive material, portions of the one or more layers of insulating material and the dielectric layer, wherein remaining portions of the one or more layers of insulating material provide the insulating layer and remaining portions of the conductive material provide the conductive layer.

19. The method of claim 15, wherein the top surfaces of the conductive layer within the trenches are coplanar with (i) a top surface of the well region and (ii) a top surface of a shallow trench isolation structure disposed surrounding the well region.

20. The method of claim 15, wherein the well region has a first conductivity type and the semiconductor layer has a second conductivity type, wherein the semiconductor layer comprises a buried layer having the first conductivity type, and wherein the trenches extend from the top surface of the semiconductor layer to the buried layer.

21. A semiconductor device, comprising:
a well region disposed in a semiconductor layer;
an array of trenches disposed within the well region, the trenches extending from a top surface of the semiconductor layer into the well region;
an insulating layer disposed on sidewalls and bottoms of the trenches;
a conductive layer disposed within the trenches, the conductive layer extending from the top surface of the semiconductor layer to the insulating layer at the bottoms of the trenches;
a first contact that provides a first terminal connecting to the well region at the top surface of the semiconductor layer; and
second contacts that provide a second terminal connecting to top surfaces of the conductive layer within the trenches.

22. The semiconductor device of claim 21, wherein the top surfaces of the conductive layer within the trenches are coplanar with a top surface of the well region.

23. The semiconductor device of claim 21, wherein the top surfaces of the conductive layer within the trenches are coplanar with a top surface of a shallow trench isolation structure disposed surrounding the well region.
